(19) United States
(12) Patent Application Publication
(10) Pub. No.: US 2010/0081246 A1
(43) Pub. Date: Apr. 1, 2010

(54) Method of manufacturing a semiconductor

(76) Inventors: Dong-Suk Shin, Yongin-si (KR); Joo-Won Lee, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/585,862

(22) Filed: Sep. 28, 2009

(30) Foreign Application Priority Data
Sep. 29, 2008 (KR) 10-2008-0095127

(51) Int. Cl. H01L 21/336

(52) U.S. Cl. 438/303; 257/E21.409

(57) ABSTRACT

A semiconductor device and a method of manufacturing a semiconductor device, the method including forming a gate insulation layer and a gate electrode on a substrate, forming a silicon nitride layer on the gate electrode and the gate insulation layer, partially implanting ions into the silicon nitride layer to convert an upper portion of the silicon nitride layer into a treated silicon layer including the ions, etching the treated silicon layer to form a spacer on a sidewall of the gate electrode, and forming an impurity region in the substrate adjacent to the gate electrode.

### BACKGROUND

1. Field

Embodiments relate to a semiconductor device and a method of manufacturing a semiconductor device.

2. Description of the Related Art

A MOSFET transistor (hereinafter, transistor) is a basic unit for forming a semiconductor device. The transistor may be operated quickly with low voltage and has been developed to be minimized and highly integrated.

When the transistor is highly integrated, a gate length of the transistor may be decreased. As the gate length decreases, a short channel effect may be generated. Also, gate resistance of the transistor may be increased. When the gate resistance increases, operation speed of the transistor may be reduced. Thus, a metal silicide pattern may be formed on the gate to reduce the gate resistance.

### SUMMARY

Embodiments are directed to a semiconductor device and a method of manufacturing a semiconductor device, which represent advances over the related art.

It is a feature of an embodiment to provide a method of manufacturing a semiconductor device including a spacer of which an upper portion and a lower portion have a substantially same width.

It is another feature of an embodiment to provide a semiconductor device having uniform characteristic distribution and high throughput.

At least one of the above and other features and advantages may be realized by providing a method of manufacturing a semiconductor device including forming a gate insulation layer and a gate electrode on a substrate, forming a silicon nitride layer on the gate electrode and the gate insulation layer, partially implanting ions into the silicon nitride layer to convert an upper portion of the silicon nitride layer into a treated silicon layer including the ions, etching the treated silicon layer to form a spacer on a sidewall of the gate electrode, and forming an impurity region in the substrate adjacent to the gate electrode.

The ions may include at least one of oxygen, carbon, and fluoride.

The step of partially implanting ions may change a property of the silicon nitride layer to form the treated silicon layer.

Etching the silicon layer to form a spacer may include one of an isotropic etching process or an anisotropic etching process.

The ions may include at least one of germanium, silicon, xenon, and argon.

Bonds between silicon and nitrogen atoms in the silicon nitride layer may be broken by the ion implantation process to form the treated silicon layer.

The silicon nitride layer may have an etching electivity with respect to the treated silicon layer.

An outside sidewall of the spacer below a center portion of the spacer may be substantially perpendicular to the substrate.

The method may further include forming a metal silicide layer pattern on the gate electrode and the impurity region.

The silicon nitride layer may be formed to a thickness of about 200 to about 500 Å.

The spacer may have a height and a width and the width may be uniform along the height.

The step of partially implanting ions may include implanting the ions at an ion implantation dose of about 1×10⁻¹⁴ to about 5×10⁻¹⁵ atoms/cm².

At least one of the above and other features and advantages may also be realized by providing a semiconductor device including a gate insulation layer and a gate electrode sequentially stacked on a substrate, a spacer contacting a sidewall of the gate electrode, wherein an outside sidewall of the spacer below a center portion of the spacer is substantially perpendicular to the substrate, and an impurity region in the substrate adjacent to the gate electrode.

The spacer may include silicon nitride.

The spacer may have a height and a width and the width may be uniform along the height.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of a MOS transistor in accordance with an embodiment;

FIGS. 2 to 5 illustrate cross-sectional views of stages in a method of manufacturing the MOS transistor of FIG. 1;

FIG. 6 illustrates a cross-sectional view of a stage in a method of manufacturing the MOS transistor of FIG. 1;

FIG. 7 illustrates a cross-sectional view of a MOS transistor in accordance another embodiment;

FIGS. 8 to 14 illustrate cross-sectional views of stages in a method of manufacturing the MOS transistor of FIG. 7; and

FIG. 15 illustrates a cross-sectional view of a stage in a method of manufacturing the MOS transistor of FIG. 7.

### DETAILED DESCRIPTION

Korean Patent Application No. 10-2008-0095127, filed on Sep. 14, 2009, in the Korean Intellectual Property Office, and entitled: “Semiconductor Device and Method of Manufacturing a Semiconductor,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “connected to” or “coupled to” another element or layer, it can be directly connected or coupled to the other element or layer or intervening elements or layers may be present. In contrast, when an element is referred to as being “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

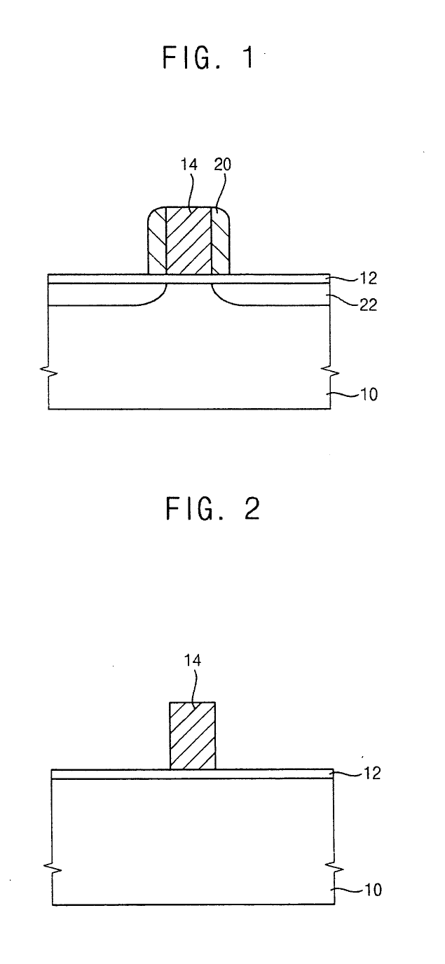

FIG. 1 illustrates a cross-sectional view of a MOS transistor in accordance with an embodiment. Referring to FIG. 1, a gate insulation layer 12 may be disposed on a semiconductor substrate 10. A gate electrode 14 may be disposed on the gate insulation layer 12. An impurity region 22 may be disposed in the substrate 10 adjacent to the gate electrode 14.

A spacer 20 may be disposed on a sidewall of the gate electrode 14. The spacer 20 may sufficiently cover an upper sidewall of the gate electrode 14. Also, a portion of a sidewall of the spacer 20 below a center portion of the spacer 20 may have a substantially perpendicular profile. In other words, an upper portion of the spacer 20 may have a width substantially the same as a width of a lower portion of the spacer 20, i.e., the spacer 20 may have a uniform width from a lower portion to an upper portion.

FIGS. 2 to 5 illustrate cross-sectional views of stages in a method of manufacturing the MOS transistor of FIG. 1. Referring to FIG. 2, a semiconductor substrate 10 may be prepared. The substrate 10 may include, e.g., a single crystalline silicon substrate, a silicon on insulator substrate, etc.

A gate insulation layer 12 may be formed on the substrate 10. The gate insulation layer 12 may be formed by, e.g., thermally oxidizing the substrate 10 or depositing a high permittivity material on the substrate 10. A conductive layer (not illustrated) may be formed on the gate insulation layer 12. The conductive layer may be patterned to form a gate electrode 14.

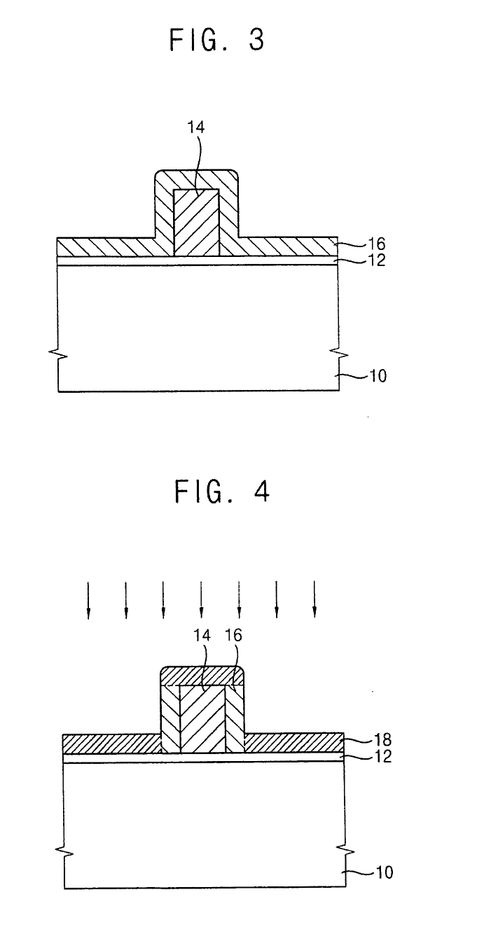

Referring to FIG. 3, a silicon nitride layer 16 may be formed on surfaces of the gate electrode 14 and the gate insulation layer 12. The silicon nitride layer 16 may be formed by, e.g., a chemical vapor deposition (CVD) process.

Referring to FIG. 4, ions may be ion-implanted into the silicon nitride layer 16 to convert an upper portion of the silicon nitride layer 16 into a treated silicon layer 18. However, the ions may not be implanted into a portion of the silicon nitride layer 16 on a sidewall of the gate electrode 14. In particular, the ion-implantation may be performed to a depth smaller than the thickness of the silicon nitride layer 16. The ions may include, e.g., oxygen, carbon, and/or fluoride.

Because the ions may be implanted into the silicon nitride layer 16 in a perpendicular direction with respect to the substrate 10, the ions may be evenly implanted with a uniform thickness along the silicon nitride layer 16. In particular, after the ion implantation process, a portion of the silicon nitride layer 16 on a sidewall of the gate electrode 14 may still remain as silicon nitride while other portions of the silicon nitride layer 16 on the gate electrode 14 and the gate insulation layer 12 may be converted into the treated silicon layer 18. As a result, a silicon layer having a different composition according to its position may be formed on surfaces of the gate electrode 14 and the gate insulation layer 12. That is, a silicon layer having different composition may be formed by partially implanting ions in the silicon nitride layer 16. For example, the treated silicon layer 18 may be formed on the gate electrode 14, a corner portion of the gate electrode 14, and the gate insulation layer 12.

Oxygen ions implanted into the silicon nitride layer 16 may have a concentration sufficient to form the respective layers having different compositions, e.g., silicon nitride and silicon oxynitride (SiON). Oxygen ions implanted into the silicon nitride layer 16 may have an implantation dose of about 1×10⁻¹⁵ to about 5×10⁻¹⁶ atoms/cm². When oxygen ions are implanted into the silicon nitride layer 16, a portion of the silicon nitride layer 16 on a sidewall of the gate electrode 14 may still remain as silicon nitride and other portions of the silicon nitride layer 16 on the gate electrode 14 and the gate insulation layer 12 may be converted into silicon oxynitride, i.e., the treated silicon layer 18.

When carbon ions are implanted into the silicon nitride layer 16, a portion of the silicon nitride layer 16 on a sidewall of the gate electrode 14 may still remain as silicon nitride and other portions of the silicon nitride layer 16 on the gate electrode 14 and the gate insulation layer 12 may be converted into silicon carbon nitride (SiCN), i.e., the treated silicon layer 18. When fluoride ions are implanted into the silicon nitride layer 16, a portion of the silicon nitride layer 16 on a sidewall of the gate electrode 14 may still remain as silicon nitride and other portions of the silicon nitride layer 16 on the gate electrode 14 and the gate insulation layer 12 may be converted into silicon fluoride (SiF) or fluorine doped silicon nitride (SiFN), i.e., the treated silicon layer 18. When the carbon ions or the fluoride ions are implanted, the carbon ions or the fluoride ions may have an implantation dose of about 1×10⁻¹⁵ to about 5×10⁻¹⁶ atoms/cm².

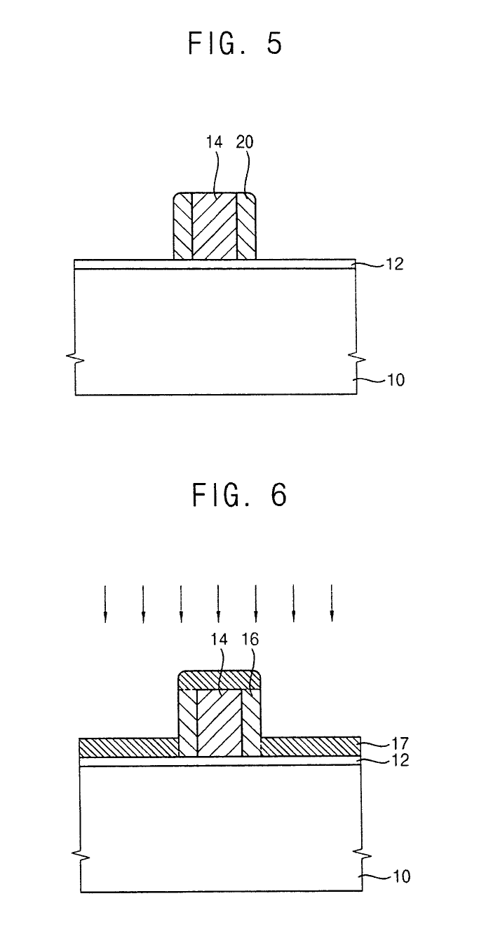

Referring to FIG. 5, the treated silicon layer 18 formed by the ion implantation process may be removed to form a spacer 20 on a sidewall of the gate electrode 14. The removal process may be performed until an upper surface of the gate insulation layer 12 and an upper surface of the gate electrode 14 are exposed. The removal process may include, e.g., an isotropic etching process and/or an anisotropic etching process.

When the removal process includes an anisotropic etching process, the silicon nitride layer 16 may not be removed and the treated silicon layer 18 may be rapidly removed. In particular, the anisotropic etching process may be performed such that the treated silicon layer 18 is selectively removed. After the anisotropic etching process, a portion of the silicon nitride layer 16 on a sidewall of the gate electrode may remain. Accordingly, the spacer 20 having an upper width and a lower width that are substantially the same as each other and an outside sidewall having a profile perpendicular to the substrate 10 may be formed. At least an outside sidewall of the spacer 20 below a center portion of a sidewall of the gate electrode 14 may have a perpendicular profile.

When the removal process includes an isotropic etching process, the treated silicon layer 18 may be selectively etched to form the spacer 20. When the spacer 20 is formed by the isotropic etching process, problems due, e.g., to ion impact may not be generated.

As illustrated in FIG. 1, the impurity region 22 may be formed by, e.g., implanting impurities into the substrate 10 adjacent to the gate electrode 14.

FIG. 6 illustrates a cross-sectional view of a stage in a method of manufacturing the MOS transistor of FIG. 1 according to another embodiment. As described with reference to FIGS. 2 and 3, the gate insulation layer 12 and the gate electrode 14 may be formed on the substrate 10. The silicon nitride layer 16 may be formed along surfaces of the gate insulation layer 12 and the gate electrode 14.

Referring to FIG. 6, ions may be implanted into the silicon nitride layer 16 to, e.g., break bonds between silicon and nitrogen included in an upper portion of the silicon nitride layer 16. The ions to break the bonds of silicon and nitrogen may include, e.g., germanium, silicon, xenon, argon, etc. These ions may be used in alone of a combination thereof.

The ions may be implanted in a direction perpendicular to the substrate 10 so that the ions are evenly implanted to predetermined depth along the silicon nitride layer 16. In particular, a portion of the silicon nitride layer 16 may remain on a sidewall of the gate electrode 14 and bonds between silicon atoms and nitrogen atoms in the silicon nitride layer 16 on the gate insulation layer 12 and on an upper portion of the gate electrode 14 may be broken. Thus, portions of the silicon nitride layer 16 in which bonds between silicon and nitrogen atoms have been broken may be converted to a treated silicon layer, e.g., a degraded silicon nitride layer 17. The ions may be implanted with a dose of about 1×10⁻¹⁴ to about 5×10⁻¹⁵ atoms/cm² in order to break the bonds between the silicon and nitrogen atoms.

The silicon nitride layer 16 and degraded silicon nitride layer 17 may be anisotropically etched to form the spacer 20 on a sidewall of the gate electrode 14 as illustrated in FIG. 5. The degraded silicon nitride layer 17 may be etched substantially faster than the other silicon nitride layer 16 by the anisotropic etching process. As a result, the spacer 20 may be rapidly formed.

Also, because the degraded silicon nitride layer 17 may be selectively etched or etched substantially faster than the silicon nitride layer 16, an upper portion of the spacer 20 may not be over-etched. As a result, the spacer 20 may cover a sidewall of the gate electrode 14, an outside sidewall of the spacer 20 may have a profile perpendicular to the substrate 10, and an upper portion of the spacer 20 may have a width substantially the same as that of a lower portion of the spacer 20.

When an isotropic etching process is performed on the degraded silicon nitride layer 17 and the silicon nitride layer 16, because the degraded silicon nitride layer 17 may not have an etching selectivity with respect to the silicon nitride layer 16 in the isotropic etching process, the spacer 20 formed by the isotropic etching process may not have a perpendicular profile with respect to the substrate 10. In addition, an upper portion of the spacer 20 may not have a width substantially the same as that of a lower portion of the spacer 20. Accordingly, an anisotropic etching process is preferred. Finally, impurities may be implanted into the substrate 10 to form an impurity region 22, thereby forming a transistor as illustrated in FIG. 1.

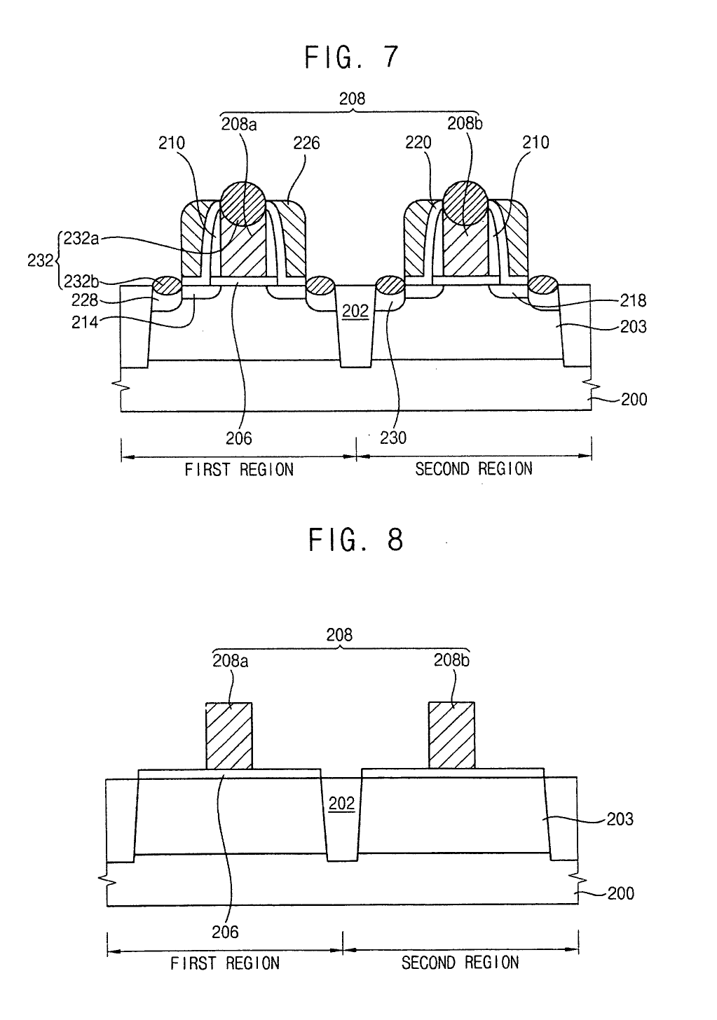

FIG. 7 illustrates a cross-sectional view of a MOS transistor in accordance with another embodiment. Referring to FIG. 7, a semiconductor substrate 200 may be prepared. The substrate 200 may be divided into a first region where an NMOS transistor may be formed and a second region where a PMOS transistor may be formed.

A gate insulation layer 206 and a first gate electrode 208a may be disposed on the first region of the substrate 200. A gate insulation layer 206 and a second gate electrode 208b may be disposed on the second region of the substrate 200. The first and second gate electrodes 208a and 208b may include, e.g., polysilicon.

An offset spacer 210 may be disposed on a sidewall of the first and second gate electrodes 208a and 208b. The offset spacer 210 may include, e.g., silicon oxide.

An etch stop layer 220 may be disposed on the offset spacer 210 and a portion of the substrate 200. The etch stop layer 220 may include, e.g., silicon oxide.

A spacer 226 may be disposed on a surface of the etch stop layer 220 on sidewalls of the first and second gate electrodes 208a and 208b. The spacer 226 may sufficiently cover upper sidewalls of the first and second gate electrodes 208a and 208b. The spacer 226 may have a lower portion having a width substantially same as that of an upper portion. At least an outside sidewall of the spacer 226 positioned below a center portion thereof may have a profile perpendicular to the substrate 200.

A first extended source/drain region 214 into which n-type impurities are doped may be disposed in the substrate 200 adjacent to the first gate electrode 208a. A first source/drain region 228 having an impurity concentration higher than that of the first extended source/drain region 214 may be disposed in the substrate 200 adjacent to the spacer 226 in the first region.

A second extended source/drain region 218 into which p-type impurities are doped may be disposed in the substrate 200 adjacent to the first gate electrode 208b. A second source/drain region 230 having an impurity concentration higher than that of the second extended source/drain region 218 may be disposed in the substrate 200 adjacent to the spacer 226 in the second region.

A first metal silicide pattern 232a may be disposed on surfaces of the first and second gate electrodes 208a and 208b. A second metal silicide pattern 232b may be disposed on the first and second source/drain regions 228 and 230. The first and second metal silicide patterns 232a and 232b may include, e.g., cobalt silicide, nickel silicide, titanium silicide, etc.

FIGS. 8 to 14 illustrate cross-sectional views of stages in a method of manufacturing the MOS transistor of FIG. 7. Referring to FIG. 8, a semiconductor substrate 200 may be prepared. The substrate 200 may be divided into a first region where an NMOS transistor is formed and a second region where a PMOS transistor is formed. A shallow trench isolation layer process may be performed on the substrate 200 to form isolation layer patterns 202, so that an active region and a field region may be defined.

After forming a first ion implanting mask pattern (not illustrated) selectively exposing the first region of the substrate 200, p-type impurities may be implanted into the first region. The p-type impurities may include, e.g., boron, boron difluoride (BF₂), etc. The first ion implanting mask pattern may then be removed. After forming a second ion implanting mask pattern (not illustrated) selectively exposing the second region of the substrate 200, n-type impurities may be implanted into the second region. The n-type impurities may include, e.g., arsenic, phosphorous, etc. The second ion implanting mask pattern may then be removed. The first and second ion implanting mask patterns may include, e.g., photoresist. Accordingly, p-type impurities may be implanted into the first region of the substrate 200 and n-type impurities may be implanted into the second region of the substrate 200 in order to form each channel region of the NMOS and PMOS transistors.

A gate insulation layer 206 may be formed on the substrate 200. The gate insulation layer 206 may be formed using, e.g., silicon oxide formed by thermally oxidizing a surface of the substrate 200. Alternatively, the gate insulation layer 206 is formed by, e.g., depositing a high permittivity material or silicon oxynitride material.

A polysilicon layer (not illustrated) may be formed on the gate insulation layer 206. The polysilicon layer may be patterned by, e.g., a photolithography process, to form first and second gate electrodes 208a and 208b on the first and second regions, respectively.

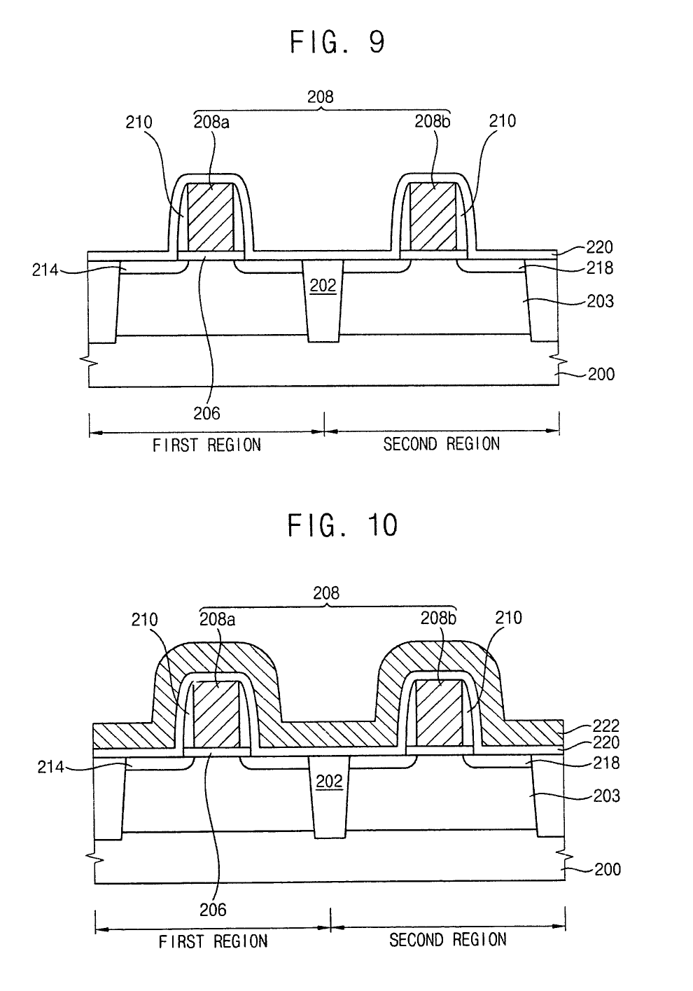

Referring to FIG. 9, an insulation layer (not illustrated) may be formed on the gate insulation layer 206 and the first and second gate electrodes 208a and 208b. The insulation layer may be formed by, e.g., a CVD process. The insulation layer and the gate insulation layer 206 may be anisotropically etched to form an offset spacer 210 on sidewalls of the first and second gate electrodes 208a and 208b. The offset spacer 210 may prevent impurities used for forming an extended impurity region from being over-diffused into a surface of the substrate 200 under the first and second gate electrodes 208a and 208b.

An ion implantation process that converts an exposed portion of the substrate 200 and the gate electrodes 208 into an amorphous state may be performed. One or more types of ions including, e.g., germanium, xenon, carbon, and/or fluoride, may be implanted into surfaces of the gate electrodes 208 and substrate 200. Exposed portions of the substrate 200 and the gate electrodes 208 may be converted into an amorphous state by the ion implantation process. As a result, an undesirable channeling effect, in which impurities used for forming a source/drain region in a successive process are laterally over-diffused, may be prevented.

A third ion implantation mask pattern (not illustrated) selectively exposing a surface of the substrate 200 in the first region may be formed on the substrate 200. N-type impurities may be implanted into the substrate 200 of the first region using the third ion implantation mask pattern as an ion implantation mask. Thus, a first extended source/drain region 214 may be formed in the substrate 200 adjacent to the first gate electrode 208a by the ion implantation.

A fourth ion implantation mask pattern (not illustrated) selectively exposing a surface of the substrate 200 in the second region may be formed on the substrate 200. P-type impurities may be implanted into the substrate 200 of the second region using the fourth ion implantation mask pattern as an ion implantation mask. Thus, a second extended source/drain region 218 may be formed in the substrate 200 adjacent to the second gate electrode 208b by the ion implantation. Also, p-type impurities may be implanted into the second gate electrode 208b to adjust a work function of the second gate electrode 208b, so that a resistance of the second gate electrode 208b may be beneficially reduced. The p-type impurities may include, e.g., boron difluoride (BF₂).

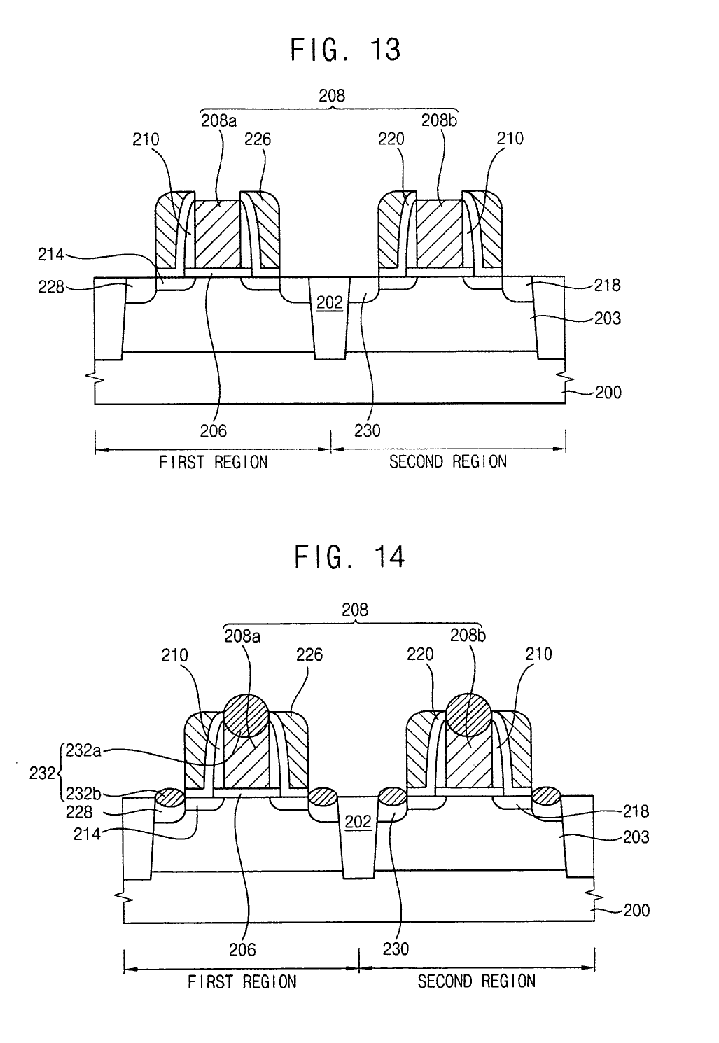

An etch stop layer 220 may be formed on surfaces of the substrate 200, the offset spacer 210, and the first and second gate electrodes 208a and 208b. The etch stop layer 220 may have an etching selectivity with respect to a spacer 226 (see FIG. 12), which may be formed in a subsequent process. For example, when the spacer 226 includes silicon nitride, the etch stop layer 220 may include silicon oxide.

Referring to FIG. 10, a silicon nitride layer 222 may be formed on the etch stop layer 220. The silicon nitride layer 222 may be formed by, e.g., a plasma enhanced chemical vapor deposition (PE-CVD) process. The silicon nitride layer 222 may be formed with a uniform thickness. For example, the silicon nitride layer 222 may have a thickness of about 200 to about 500 Å. Alternatively, the silicon nitride layer 222 may have a different thickness according to the semiconductor device being fabricated.

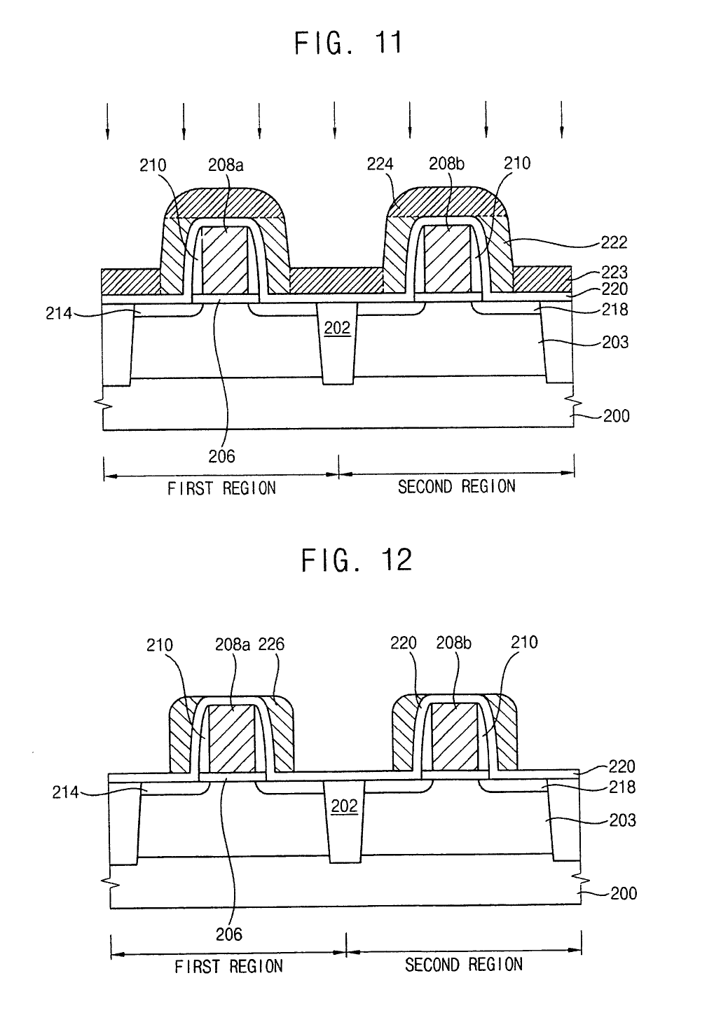

Referring to FIG. 11, ions may be ion-implanted into the silicon nitride layer 222 to partially convert an upper portion of the silicon nitride layer 222 into a treated silicon layer 224. However, the ions may not be implanted into a portion of the silicon nitride layer 222 on a sidewall of the gate electrode 208. An ion-implantation depth may be substantially the same as or smaller than a thickness of the silicon nitride layer 222. The ions may include, e.g., oxygen, carbon, and/or fluoride. A portion of the silicon nitride layer 222 on a sidewall of the gate electrodes 208 may remain unchanged, and portions of silicon nitride layer 222 on the gate insulation layer 206 and an upper surface of the gate electrodes 208 may be converted into the treated silicon layer 224. The ions implanted into the silicon nitride layer 222 may have a sufficient concentration to form the treated silicon layer 224 having different characteristics from the silicon nitride layer 222.

The ions, e.g., oxygen, carbon, fluoride, etc., may be used alone or in a combination thereof. Oxygen ions implanted into the silicon nitride layer 222 may have a concentration sufficient to form the respective layers having different compositions, e.g., silicon nitride and silicon oxynitride (SiON). Oxygen ions implanted into the silicon nitride layer 16 may have an ion implantation dose of about 1×10⁻¹⁵ to about 5×10⁻¹⁶ atoms/cm². When oxygen ions are implanted into the silicon nitride layer 222, a portion of the silicon nitride layer 222 on a sidewall of the gate electrode 208 may still remain as silicon nitride and other portions of the silicon nitride layer 222 on the gate electrode 208 and the etch stop layer 220 may be converted into silicon oxynitride, i.e., the treated silicon layer 224.

When carbon ions are implanted into the silicon nitride layer 222, a portion of the silicon nitride layer 222 on a sidewall of the gate electrode 208 may still remain as silicon nitride and other portions of the silicon nitride layer 222 on the gate electrode 208 and the etch stop layer 220 may be converted into silicon carbon nitride (SiCN), i.e., the treated silicon layer 224. When fluoride ions are implanted into the silicon nitride layer 222, a portion of the silicon nitride layer 222 on a sidewall of the gate electrode 208 may still remain as silicon nitride and other portions of the silicon nitride layer 222 on the gate electrode 208 and the etch stop layer 220 may be converted into silicon fluoride (SiF) or fluorine doped silicon nitride (SiFN), i.e., the treated silicon layer 224. When the carbon ions or the fluoride ions are implanted, the carbon ions or the fluoride ions may have an ion implantation dose of about 1×10⁻¹⁵ to about 5×10⁻¹⁶ atoms/cm².

Referring to FIG. 12, the treated silicon layer 224 formed by the ion implantation process may be etched to form a spacer 226 on a sidewall of the gate electrodes 208a and 208b. The etching process may be performed until an upper surface of the etch stop layer 220 is exposed. The etching process may include, e.g., an isotropic etching process and/or an anisotropic etching process.

As illustrated in FIG. 12, an outside sidewall of the spacer 226 below a center portion thereof and of the gate electrodes 208a and 208b may have a profile perpendicular to the substrate 200. Also, an upper portion of the spacer 226 may have a width substantially the same as that of the lower portion of the spacer 226.

Referring to FIG. 13, a fifth ion implantation mask pattern (not illustrated) selectively exposing a surface of the substrate 200 of the first region may be formed. The fifth ion implantation mask pattern may include, e.g., a photoresist pattern.

N-type impurities may be implanted into the substrate 200 of the first region using the fifth ion implantation mask pattern as an ion implantation mask. A first source/drain region 228 may be formed in the substrate 200 adjacent to the first gate electrode 208a by the ion implantation. The n-type impurities may also be implanted into the first gate electrode 208a to adjust a work function of the first gate electrode 208a, so that resistance of the first gate electrode 208a may be advantageously reduced.

A sixth ion implantation mask pattern (not illustrated) selectively exposing a surface of the substrate 200 in the second region may be formed on the substrate 200. P-type impurities may be implanted into the substrate 200 of the second region using the sixth ion implantation mask pattern as an ion implantation mask. A second source/drain region 230 may be formed in the substrate 200 adjacent to the second gate electrode 208b by the ion implantation. Also, p-type impurities may be implanted into the second gate electrode 208b to adjust a work function of the second gate electrode 208b, so that resistance of the second gate electrode 208b may be beneficially reduced.

Exposed portions of the etch stop layer 220 may be removed. The etch stop layer may be removed by, e.g., a chemical dry etching process and/or a wet etching process. The etch stop layer may be removed prior to forming the first and second source/drain regions 228 and 230.

Referring to FIG. 14, a metal layer (not illustrated) may be formed on upper surfaces of the gate electrodes 208a and 208b, the substrate 200, and the spacer 226. The metal layer may react with silicon to form a metal silicide layer pattern. The metal layer may include, e.g., cobalt, nickel, titanium, etc. These may be used in alone or a combination thereof.

A thermal heating process may be performed on the metal layer to react the metal layer with the substrate 200 and upper surfaces of the gate electrodes 208a and 208b to form a first metal silicide layer pattern 232a and a second metal silicide layer pattern 232b. The first metal silicide layer pattern 232a may be formed on upper surfaces of the first and second gate electrodes 208a and 208b. The second metal silicide layer pattern 232a may be formed on upper surfaces of the first and second source/drain regions 228 and 230. The thermal heating process may include, e.g., a rapid thermal process and/or a thermal heating process using a furnace.

The thermal heating process for forming the metal silicide layer patterns 232a and 232b may be performed two or more times at different temperatures, respectively. Alternatively, a capping layer may be formed on the metal layer. For example, when cobalt is used as the metal layer, a first thermal process may be performed at a first temperature to react cobalt with silicon, so that a first layer (not illustrated) including Co₂Si and/or CoSi may be formed. A capping layer (not illustrated) including, e.g., titanium/titanium nitride, may be formed on the first layer. A second thermal process may then be performed at a second temperature higher than the first temperature to form a metal silicide layer pattern including CoSi₂.

Unreacted portions of the metal layer may be removed after forming the metal silicide patterns 232a and 232b. The removal process may be performed by, e.g., an isotropic etching process.

The spacer 226 may sufficiently cover a sidewall of the gate electrodes 208a and 208b. The spacer 226 may have a uniform thickness along its height. For example, an upper portion of the spacer 226 may have a width substantially the same as that of the lower portion of the spacer 226. Thus, when the first metal silicide layer pattern 232a are formed, the metal layer covering the gate electrodes 208a and 208b may not contact sidewalls of the gate electrodes 208a and 208b, but may contact only an upper surface of the gate electrodes 208a and 208b. As a result, a reaction of the metal layer and the gate electrodes 208a and 208b may be restricted to an upper surface of the gate electrodes 208a and 208b. Thus, an undesirable change of threshold voltage of a transistor due to over-growth of the metal silicide layer pattern in a process forming the first metal silicide layer pattern 232a may not be generated. Accordingly, characteristic distribution of a semiconductor device may be uniform and throughput of a semiconductor device may be increased.

When the spacer 226 does not sufficiently cover a sidewall of the gate electrodes 208a and 208b, or an upper portion of the spacer 226 has a relatively small thickness, problems may occur during formation of the first metal silicide layer patterns 232a. Particularly, because the spacer 226 may be eroded by continuous washing processes, it may be difficult for the spacer 226 to have a good profile.

For example, when the spacer 226 does not sufficiently cover upper sidewalls of the gate electrodes 208a and 208b, the metal layer may contact the upper sidewalls of the gate electrodes 208a and 208b as well as an upper surface of the gate electrodes 208a and 208b. Accordingly, when the silicidation process is performed, the metal layer may react with silicon of the upper sidewall of the gate electrodes 208a and 208b as well as the upper surface of the gate electrodes 208a and 208b. As a result, the first metal silicide layer pattern 232a may be excessively formed on the upper sidewall of the gate electrodes 208a and 208b. Additionally, the first metal silicide layer pattern 232a may be excessively formed on a lower sidewall of the gate electrodes 208a and 208b. In this case, the first metal silicide layer pattern 232a may not have a desirable shape, and thus a threshold voltage of the transistor may be changed. Also, the first metal silicide layer patterns 232a formed on a plurality of gate electrodes 208 may not have uniform shapes, respectively, so that non-uniform characteristic distributions of the semiconductor device may be undesirably increased.

According to the present embodiment, a spacer 226 sufficiently covering the sidewall of the gate electrode 208 and having a lower portion and an upper portion with substantially the same width may be formed. Thus, problems due to an uneven shape of the spacer 226 may be reduced.

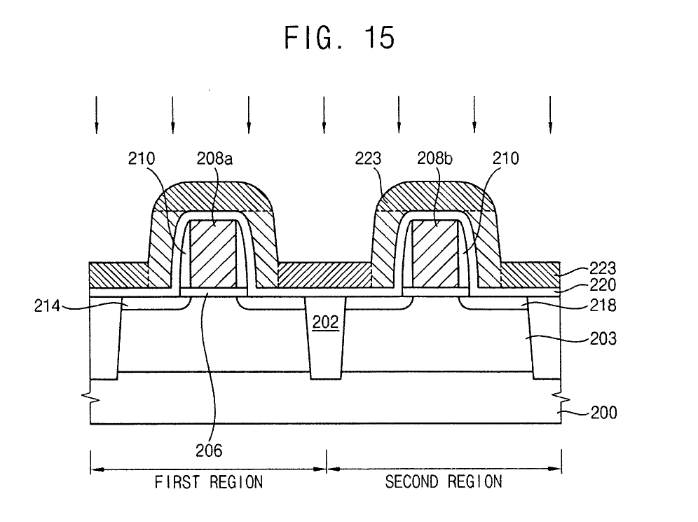

FIG. 15 illustrates a cross-sectional view of a stage in a method of manufacturing the MOS transistor of FIG. 7 according to another embodiment. Referring to FIG. 15, a gate insulation layer 206 and the first and second gate electrodes 208a and 208b may be formed on a substrate 200 as described with reference to FIGS. 8 to 10. An offset spacer 210 may be formed on sidewalls of first and second gate electrodes 208a and 208b. First and second extended source/drain region 214 and 218 may be formed on the substrate 200. An etch stop layer 220 may be formed on surfaces of the substrate 200 and first and second gate electrodes 208a and 208b. A silicon nitride layer 222 may be formed on the etch stop layer 220. Ions may be implanted into an upper surface of the silicon nitride layer 222 to break bonds between silicon and nitrogen atoms in an upper portion of the silicon nitride layer 222. The ions for breaking the bonds may include, e.g., germanium, silicon, xenon, and/or argon. The ions may be implanted with a dose of about 1×10⁻¹⁴ to about 5×10⁻¹⁵ atoms/cm² in order to break bonds between silicon atoms and nitrogen atoms. After performing the ion implantation process, the silicon nitride layer 222 on the sidewalls of the gate electrodes 208a and 208b may remain unchanged. Bonds between silicon and nitrogen atoms in the silicon nitride layer 222 on the gate electrodes 208a and 208b and on the etch stop layer 220 may be broken and the layer may be converted into a treated silicon layer, e.g., a degraded silicon nitride layer 223.

As illustrated in FIG. 12, the degraded silicon nitride layer 223 may be removed by, e.g., an isotropic etching process, to form a spacer 226 on sidewalls of the gate electrodes 208a and 208b. The degraded silicon nitride layer 223 may be etched more rapidly than the silicon nitride layer 222 by the isotropic etching process.

Because bonds between silicon and nitrogen atoms in the degraded silicon nitride layer 223 may be broken, an upper portion of the spacer 226 may not be excessively etched. Accordingly, as illustrated in FIG. 12, the spacer 226 may sufficiently cover a sidewall of the gate electrodes 208a and 208b, and may have a profile perpendicular to the substrate 200. In addition, a lower portion and an upper of the spacer 226 may have widths that are substantially the same as each other.

First and second source/drain regions 228 and 230 may be formed in the substrate 200 adjacent to the first and second gate electrodes 208a and 208b, respectively, as described with reference to FIGS. 13 and 14. Metal silicide layer patterns 232a and 232b may be formed on the gate electrodes 208a and 208b and on the first and second source/drain regions 228 and 230, respectively.

By way of review, generally, a spacer may be formed on sidewalls of the gate of the transistor. Only an upper surface of the gate may be exposed by the spacer so that a portion on which the metal silicide pattern is formed is defined. Also, the spacer may define a portion on which an impurity region adjacent to the gate may be formed.

Thus, it may be desirable for the spacers to have a uniform shape with respect to an entire substrate. Also, it may be desirable that the spacer covers a sidewall of the gate and has a uniform width from an upper portion of the spacer to a lower portion of the spacer.

More specifically, according to an embodiment, the spacer may sufficiently cover a sidewall of the gate electrodes, may have a profile perpendicular to the substrate, and may have a lower portion and an upper portion having widths that are substantially the same as each other. Thus, a MOS transistor having a uniform characteristic distribution along an entire substrate region may be manufactured. The embodiments may be used to fabricate a semiconductor device including a MOS transistor, especially a memory device requiring a uniform characteristic distribution.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of manufacturing a semiconductor device, comprising:
forming a gate insulation layer and a gate electrode on a substrate;
forming a silicon nitride layer on the gate electrode and the gate insulation layer;
partially implanting ions into the silicon nitride layer to convert an upper portion of the silicon nitride layer into a treated silicon layer including the ions;
etching the treated silicon layer to form a spacer on a sidewall of the gate electrode; and
forming an impurity region in the substrate adjacent to the gate electrode.

2. The method as claimed in claim 1, wherein the ions include at least one of oxygen, carbon, and fluoride.

3. The method as claimed in claim 2, wherein the step of partially implanting ions changes a property of the silicon nitride layer to form the treated silicon layer.

4. The method as claimed in claim 2, wherein etching the silicon layer to form a spacer includes one of an isotropic etching process or an anisotropic etching process.

5. The method as claimed in claim 1, wherein the ions include at least one of germanium, silicon, xenon, and argon.

6. The method as claimed in claim 5, wherein bonds between silicon and nitrogen atoms in the silicon nitride layer are broken by the ion implantation process to form the treated silicon layer.

7. The method as claimed in claim 1, wherein the silicon nitride layer has an etching electivity with respect to the treated silicon layer.

8. The method as claimed in claim 1, wherein an outside sidewall of the spacer below a center portion of the spacer is substantially perpendicular to the substrate.

9. The method as claimed in claim 1, further comprising forming a metal silicide layer pattern on the gate electrode and the impurity region.

10. The method as claimed in claim 1 wherein the silicon nitride layer is formed to a thickness of about 200 to about 500 Å.

11. The method as claimed in claim 1 wherein the spacer has a height and a width and the width is uniform along the height.

12. The method as claimed in claim 1, wherein the step of partially implanting ions may include implanting the ions at an ion implantation dose of about 1×10⁻¹⁴ to about 5×10⁻¹⁵ atoms/cm².

13-15. (canceled)
